(19) United States
(12) Patent Application Publication
(10) Pub. No.: US 2023/0246141 A1
(43) Pub. Date: Aug. 3, 2023

(54) OPTOELECTRONIC COMPONENT AND METHOD FOR PRODUCING AN OPTOELECTRONIC COMPONENT

(71) Applicant: ams-OSRAM International GmbH, Regensburg (DE)

(72) Inventors: Angela EBERHARDT, Augsburg (DE); Florian PESKOLLER, Ingolstadt (DE); Nusret Sena RICHTER, Regensburg (DE)

(21) Appl. No.: 18/008,068

(22) PCT Filed: May 28, 2021
(86) PCT No.: PCT/EP2021/064386

§ 371 Date: Dec. 2, 2022

(30) Foreign Application Priority Data
Jun. 3, 2020 (DE) 10 2020 206 897.6

(51) Int. Cl. H01L 33/50

(52) U.S. Cl. CPC H01L 33/501; H01L 2933/0041

(57) ABSTRACT

The invention relates to an optoelectronic component comprising—a semiconductor chip that emits primary electromagnetic radiation of a first wavelength range during operation and—a conversion element, wherein the conversion element comprises a wavelength-converting material and a matrix material, wherein the matrix material includes a polysiloxane having at least 90 wt. % condensed silicates relative to the total weight of the matrix material, and the condensed silicate consists of silicon atoms and oxygen atoms. The conversion element is designed to emit secondary electromagnetic radiation of a second wavelength range, and the conversion element is arranged after the semiconductor chip and an adhesion-promoting layer is arranged between the conversion element and the semiconductor chip, and/or a carrier is arranged on the side of the conversion element facing away from the semiconductor chip.

An optoelectronic component and a method for producing an optoelectronic component are specified.

One object to be achieved is that of specifying an improved optoelectronic component. A further object to be achieved is that of specifying a method for producing an optoelectronic component having improved properties.

According to at least one embodiment, the optoelectronic component comprises a semiconductor chip that emits electromagnetic primary radiation of a first wavelength range during operation. The semiconductor chip is based for example on a flip chip; that is to say that both electrical contacts are arranged on one side of the semiconductor chip. Furthermore, the electrical contacts may each be located on the upper side and on the lower side of the semiconductor chip. During operation, the semiconductor chip can emit for example electromagnetic radiation from a wavelength range of UV radiation, visible light and/or infrared range.

According to at least one embodiment, the optoelectronic component has a conversion element, wherein the conversion element comprises a wavelength-converting material and a matrix material.

According to at least one embodiment, the conversion element is configured to emit electromagnetic secondary radiation of a second wavelength range. The wavelength-converting material converts part of the primary radiation of the semiconductor chip into secondary radiation, whereas a further part of the primary radiation of the semiconductor chip is transmitted by the conversion element.

The wavelength-converting material is a ceramic phosphor, for example. In particular, the ceramic phosphors include a garnet phosphor, a nitride phosphor or a combination thereof. Preferably, the garnet phosphor is a YAG phosphor, Y₃Al₅O₁₂:Ce³⁺; a LuAG phosphor, Lu₃Al₅O₁₂:Ce³⁺; a YAGaG phosphor, Y₃(Al,Ga)₅O₁₂:Ce³⁺ and/or a LuAGaG phosphor, Lu₃(Al,Ga)₅O₁₂:Ce³⁺. The nitride phosphor may for example be an alkaline earth metal silicon nitride, an oxynitride, an aluminum oxynitride, a silicon nitride or a SiAlON. By way of example, the nitride phosphor is La₃Si₆N₁₁:Ce³⁺ (LSN), (La,Y)₃Si₆N₁₁:Ce³⁺ (LYSN), (Sr,Ba)SiON:Eu, α-SiAlON:Eu, β-SiAlON: Eu, (Ca,Sr,Ba)AlSiN₃:Eu²⁺ (CASN), Sr(Ca,Sr)Al₂Si₂N₆:Eu²⁺ (SCASN) or M₂Si₅N₈:Eu²⁺ where M=Ca, Ba or Sr alone or in combination. The nitride phosphors preferably convert blue primary radiation into red secondary radiation.

According to at least one embodiment, the wavelength-converting material or the ceramic phosphor is in the form of particles, wherein the particles are at a distance of at most 20 μm, preferably of at most 15 μm, particularly preferably of at most 10 μm or 5 μm, very particularly preferably of at most 1 μm from one another. By way of example and preferably, there is direct contact between the particles. In other words, the conversion element has a high degree of filling with wavelength-converting material. As a result, it is possible to keep the spatial extent, particularly the thickness, of the conversion element low and to readily dissipate the resulting heat.

According to at least one embodiment of the optoelectronic component, the matrix material comprises a polysiloxane which comprises at least 90% by weight, based on the total weight of the matrix material, of condensed silicates. In particular, the polysiloxane comprises purely inorganic constituents. That is to say that the polysiloxane preferably does not comprise any organic radicals, such as alkyl groups. By way of example, the fraction of organic radicals such as alkyl groups is at most 1% by weight based on the total weight of the matrix material. The reduction in organic radicals makes it possible to significantly increase the thermal conductivity. The matrix material can additionally comprise alkali metal ions if the matrix material is a waterglass.

According to at least one embodiment of the optoelectronic component, the condensed silicate consists of silicon atoms and oxygen atoms. That is to say that each silicon atom of the condensed silicate is bonded to four oxygen atoms, which in turn are bonded to a further four silicon atoms. In particular, the condensed silicate is SiO₂.

According to at least one embodiment, the matrix material consists of the condensed silicate, preferably of SiO₂. The matrix material is thus free from organic radicals and thereby has a very high thermal conductivity in combination with the high degree of filling.

According to at least one embodiment, the conversion element is downstream of the semiconductor chip and an adhesion-promoter layer is arranged between the conversion element and the semiconductor chip. The adhesion-promoter layer comprises a matrix and optionally a luminescent material. The luminescent material is particularly selected from the group of the wavelength-converting materials. The matrix comprises a siloxane which may comprise organic components. That is to say that at least the silicon atom of the siloxane is bonded to at least two or three oxygen atoms, which in turn are bonded to further silicon atoms. The other two substituents may be an organic group, for example an alkyl group. The fraction of organic radicals is preferably below 81% by weight in order to ensure good thermal conduction. Suitable siloxanes are described in WO 2017/182390 A1. If the luminescent material is embedded in the adhesion-promoter layer, then this can be equated with the conversion element. The production of a layer of siloxane and luminescent material is described for example in WO 2018/002334 A1.

According to at least one embodiment of the optoelectronic component, the conversion element comprises nanofillers and/or microfillers. The nanofillers are particularly pyrogenic silicon dioxide particles, zirconium dioxide particles or a combination thereof. The microfillers comprise glass particles, such as glass quartz beads. The nanofillers have an average diameter of between at least 1 nm and at most 1000 nm, in particular of between at least 1 nm and at most 100 nm. The microfillers have an average diameter of between at least 500 nm and at most 100 μm, in particular of between at least 1 μm and at most 10 μm. The average diameter is determined by the D50 value. This means that 50% of the nanofillers or of the microfillers are smaller than the stated value. The nanofillers increase the viscosity of the matrix material during production and therefore reduce crack formation. The microfillers serve to fill cavities in the conversion element.

According to at least one embodiment, the nanofillers account for up to at most 30% by volume based on the matrix material.

According to at least one embodiment, the wavelength-converting material or the ceramic phosphor and the nanofillers are in the form of particles. These particles are at a distance of at most 20 μm, preferably of at most 15 μm, particularly preferably of at most 10 μm or 5 μm, very particularly preferably of at most 1 μm from one another. By way of example and preferably, there is direct contact between the particles. In other words, the conversion element has a high degree of filling with wavelength-converting material and nanofillers and/or microfillers.

According to at least one embodiment, the conversion element is embodied as a layer and has a thickness of up to 100 μm. In particular, the conversion element has a thickness of up to 50 μm. For example, the conversion element has a thickness of at least 5 μm. Such small thicknesses are particularly possible since a high degree of filling with wavelength-converting material in the conversion element can be realized.

According to at least one embodiment of the optoelectronic component, the second wavelength range is in the spectral range of amber light. The conversion element here has a green phosphor and a red phosphor as wavelength-converting material. The red phosphor may for example be a nitride phosphor. The green phosphor may for example be a garnet. An emission maximum of amber light is particularly between at least 550 nm and at most 610 nm. By way of example, the emission maximum of amber light is between at least 570 nm and at most 600 nm.

The greater Stokes shift and stronger thermal quenching mean that red phosphors are particularly critical for high operating currents and operating temperatures. Embedding into the matrix material according to the invention, in particular SiO₂, is therefore particularly advantageous, since said matrix material dissipates the heat produced very well, especially in conjunction with a high degree of filling. It is possible to very significantly increase the thermal conductivity and the temperature resistance compared with a matrix made of siloxane having organic components.

According to at least one embodiment, a support is arranged on the side of the conversion element that faces away from the semiconductor chip. In particular, the support is a glass substrate which for example is a borosilicate glass, soda-lime glass, crown glass, aluminosilicate glass, hard glass, in particular alkali metal-free, or a quartz glass. The support serves, inter alia, to stabilize the optoelectronic component and to protect the conversion element from external influences. The support may also be a sapphire or a glass ceramic.

A method for producing an optoelectronic component is also specified. In particular, the method described here for producing an optoelectronic component can be used to produce an optoelectronic component described here. This means that all features disclosed for the method for producing optoelectronic components are also disclosed for the optoelectronic component, and vice versa.

According to at least one embodiment of the method for producing an optoelectronic component, a semiconductor chip configured to emit primary radiation of a first wavelength range during operation is provided. In a further method step, a conversion element described here or a precursor of a conversion element described here which is configured to emit secondary radiation of a second wavelength range is produced. The precursor of the conversion element comprises a mixture and a sol-gel solution. The mixture comprises microfillers and at least one wavelength-converting material. The sol-gel solution comprises a silicate, a nanofiller and an acid. Preferably, the sol-gel solution comprises a tetraethyl orthosilicate and/or tetramethyl orthosilicate as silicate. Instead of the sol-gel solution, a waterglass, for example a sodium waterglass, potassium waterglass or lithium waterglass, as well as mixtures thereof, can optionally be used in conjunction with nanofillers.

The use of tetraethyl orthosilicate and/or tetramethyl orthosilicate in particular enables complete condensation, such that the resulting matrix material is SiO₂.

According to at least one embodiment, the conversion element or the precursor of the conversion element is applied to the semiconductor chip.

According to at least one embodiment, the conversion element is arranged on the semiconductor chip by means of an adhesion-promoter layer.

According to at least one embodiment, the adhesion-promoter layer is at most 5 μm thick, preferably at most 3 μm, for example between 1 μm and 3 μm.

According to at least one embodiment, the conversion element is formed on a support and the side of the conversion element that faces away from the support is applied to the semiconductor chip. When producing the conversion element on the support, the precursor of the conversion element is first applied to the support. The support may be coated several times with the precursor of the conversion element. The precursor of the conversion element is then subsequently coated with a clear sol-gel solution. The clear sol-gel solution comprises merely the silicate, which is acid-catalyzed. The process can be repeated several times. Finally, an inactive layer is applied that is either the clear sol-gel solution or a siloxane-based solution. The precursor of the conversion element is cured and singulated and the side thereof that faces away from the support can then be applied to the semiconductor chip.

According to at least one embodiment, the conversion element is formed on the semiconductor chip. Here, the precursor of the conversion element is applied directly to the semiconductor chip. The application is effected analogously to the application to the support.

According to at least one embodiment, the method temperature is at most 400° C. Preferably, the method temperature is at most 350° C. The comparatively low method temperature makes it possible to ensure that optionally present red phosphor does not sustain permanent damage due to high process-related temperatures.

One concept of the present optoelectronic component is to synthesize a highly filled, purely inorganic conversion element with a matrix material made of condensed silicates. The conversion element in this case is particularly suitable for high-current applications, for example ≥1 A for 1 mm² of chip. The conversion element has little cracking and has a high density.

Furthermore, an adhesion-promoter layer can advantageously serve as a barrier layer and therefore prevent undesirable reactions between the matrix material of the conversion element and the surface of the semiconductor chip. Moreover, the conversion element is well suited for high-current amber applications with high CRI (“color rendering index”) and high R9 value, since in this case a large amount of heat is released as a result of the relatively high current, for example ≥1 A, and advantages are achieved with respect to comparative conversion elements such as a phosphor mixture in a polymer matrix, a phosphor ceramic or a phosphor mixture in a glass matrix on account of the better thermal conductivity and/or lower production temperature and of the good temperature resistance. Using the production of the conversion element on a support enables a slightly higher curing temperature and thus a more stable layer in comparison with the direct application to a semiconductor chip. Nevertheless, the conversion element can be produced at relatively low temperatures and there is therefore no damage to red-emitting phosphors.

Further advantageous embodiments and developments of the optoelectronic component and of the method for producing an optoelectronic component emerge from the exemplary embodiments described below in conjunction with the figures.

In the figures:

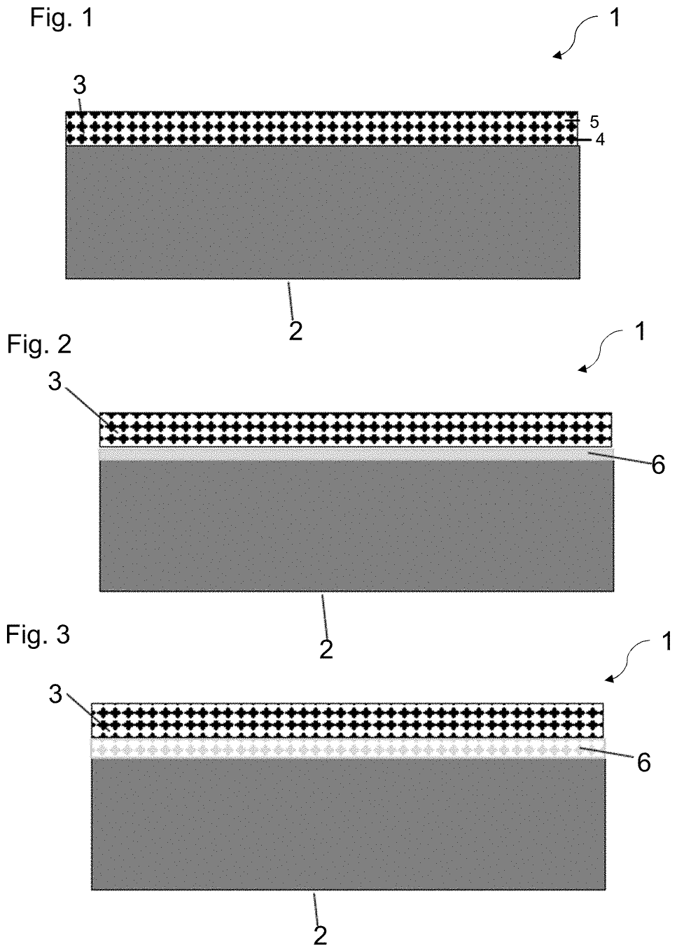

FIGS. 1 to 5 show schematic sectional views of an optoelectronic component each according to one exemplary embodiment,

FIG. 6 shows a plan view of an optoelectronic component after singulation according to one exemplary embodiment,

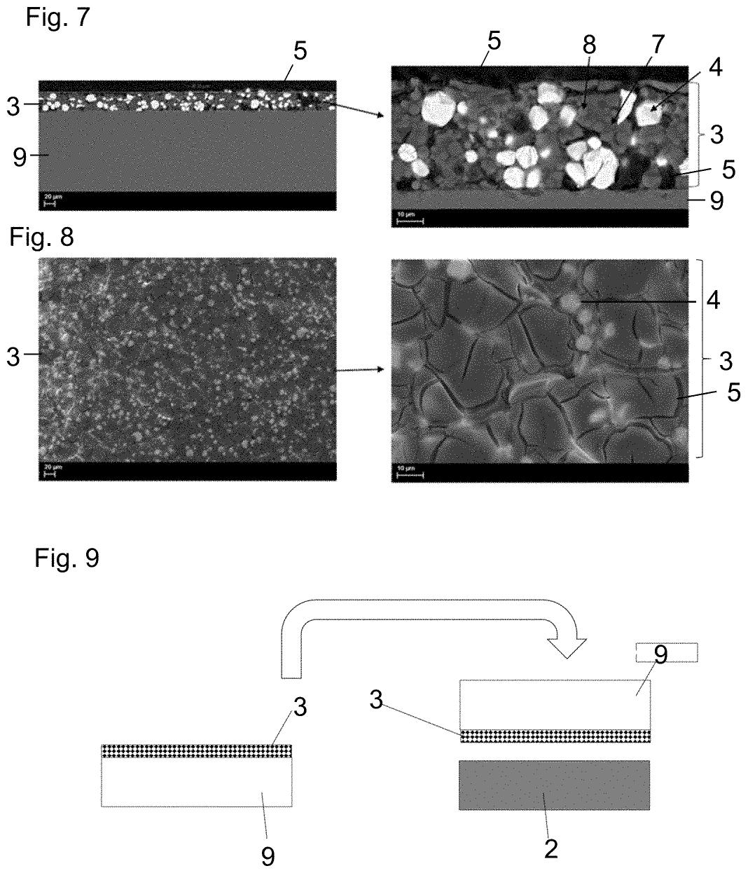

FIG. 7 shows a cross section of a layer structure according to one exemplary embodiment,

FIG. 8 shows a layer surface of a layer structure according to one exemplary embodiment and

FIG. 9 shows a method for producing an optoelectronic component according to one exemplary embodiment.

Like elements, elements of the same kind or identically acting elements have been provided with the same reference signs in the figures. The figures and the proportions of the elements depicted in the figures with respect to one another should not be considered to be true to scale. Rather, individual elements, especially layer thicknesses, may be depicted with an exaggerated size for clarity of presentation and/or for clarity of understanding.

The optoelectronic component 1 according to the exemplary embodiment of FIG. 1 has a semiconductor chip 2 and a conversion element 3. The conversion element 3 is applied directly to the surface of the semiconductor chip 2. A passivation layer, for example an SiO₂ layer or an Al₂O₃ layer, can optionally be arranged between the conversion element 3 and the semiconductor chip 2. The conversion element 3 comprises a wavelength-converting material 4 and a matrix material 5. The matrix material 5 comprises a polysiloxane which comprises at least 90% by weight based on the total weight of the matrix material 5 of condensed silicates. The condensed silicate in turn consists of silicon atoms and oxygen atoms. That is to say that each silicon atom is bridged via four oxygen atoms to one further silicon atom each. The fraction of organic radicals such as alkyl groups is at most 1% by weight based on the total weight of the matrix material 5; preferably, the matrix material consists of SiO₂. The wavelength-converting material 4 is a garnet phosphor, a nitride phosphor or a combination thereof.

FIG. 2 also shows an optoelectronic component 1 according to one exemplary embodiment. The optoelectronic component 1 of FIG. 2 differs from the optoelectronic component 1 of FIG. 1 by the fact that an adhesion-promoter layer 6 is arranged between the semiconductor chip 2 and the conversion element 3. The adhesion-promoter layer 6 is applied directly to the surface of the semiconductor chip 2 and crosslinked. The adhesion-promoter layer 6 has a thickness in the low single-digit micrometer range so as to not serve as a heat barrier.

The exemplary embodiment of FIG. 3 shows an optoelectronic component 1 that differs from the optoelectronic component 1 of FIG. 2 by the fact that a luminescent material is embedded in the adhesion-promoter layer 6. The adhesion-promoter layer 6 is thicker here than the adhesion-promoter layer 6 in FIG. 2. Here, the adhesion-promoter layer 6 has a thickness of several micrometers. The luminescent material in the adhesion-promoter layer 6 here does not have to be completely covered with the siloxane of the adhesion-promoter layer 6, but can also be surrounded by the matrix material 5 of the conversion element 3.

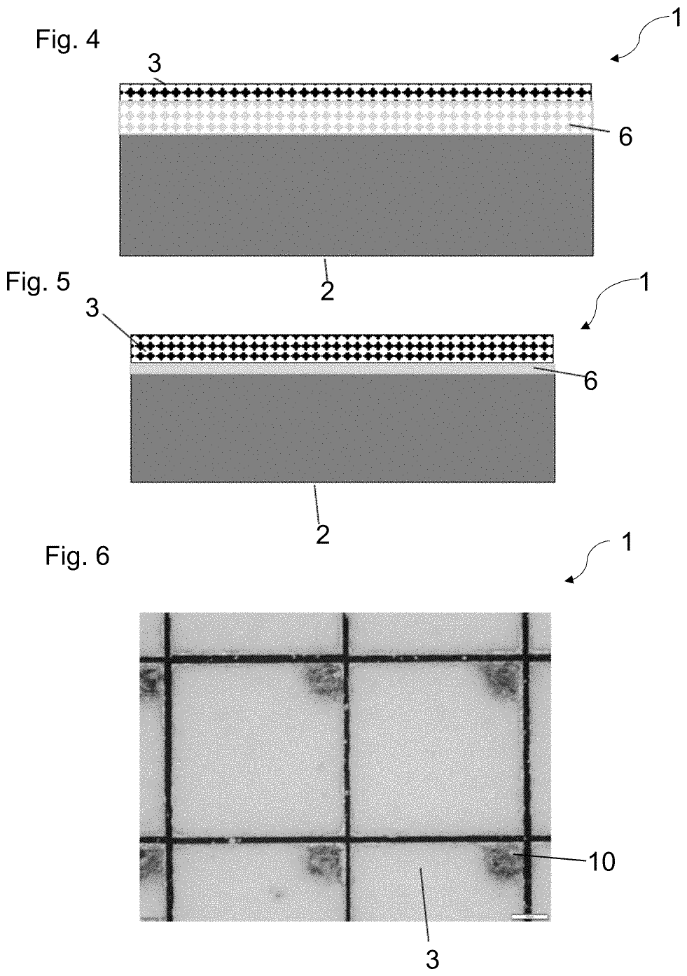

In comparison with the exemplary embodiment of FIG. 3, the exemplary embodiment of FIG. 4 shows a thicker adhesion-promoter layer 6. The adhesion-promoter layer 6 has a thickness of thicker than 10 μm. The conversion element 3 can optionally be arranged on the adhesion-promoter layer 6. The adhesion-promoter layer 6 can serve as conversion element 3.

The exemplary embodiment of FIG. 5 shows an optoelectronic component 1 which differs from the exemplary embodiment of FIG. 2 by the fact that the adhesion-promoter layer 6 here serves as a barrier layer between the conversion element 3 and the semiconductor chip 2. This prevents undesirable reactions or ion migrations between the matrix material 5 of the conversion element 3 and the surface of the semiconductor chip 2. For example, under moist conditions this would be a reaction between GaN and a waterglass as matrix material 5. The adhesion-promoter layer 6 can act both as a barrier layer and as an adhesion promoter.

FIG. 6 shows a plan view of a conversion element 3 on a semiconductor chip 2 with an oxidic passivation SiO₂ after singulation. The optoelectronic component 1 has already been singulated here. The electrical contacts 10 of the semiconductor chip 2 can also be seen.

FIG. 7 shows a conversion element 3 on a support 9 according to one exemplary embodiment. The support 9 is made of glass. The conversion element 3 comprises nanofillers 7, microfillers 8, a wavelength-converting material 4 and a matrix material 5. The thickness of the conversion element 3 is approximately 40 μm in this case. There is a layer of matrix material 5 or of a siloxane on the side of the conversion element 3 that faces away from the support 9.

FIG. 8 shows a conversion element 3 in plan view. The wavelength-converting material 4 can be seen here. The cracks between the individual regions were caused by the method and are filled with the matrix material 5.

FIG. 9 describes the method for producing an optoelectronic component 1 according to one exemplary embodiment. A support 9 made of borosilicate glass is first provided. The support 9 is coated with a precursor of the conversion element 3. The precursor of the conversion element 3 comprises a mixture of green and red phosphors and glass particles, for example quartz glass beads, which is suspended in a sol-gel solution. The sol-gel solution comprises TEOS, an acid and pyrogenic SiO₂. The coating may be effected several times. Subsequent coating is then effected with a clear sol-gel solution, without pyrogenic SiO₂. A layer that is as dense as possible is thereby obtained. The layer is dried at room temperature between the individual steps. The matrix material 5 is then dried at elevated temperature, for example at 80° C., and crosslinked at up to 400° C., ideally at no more than 350° C. To compact the layer further, after this step coating can be effected once again with the clear sol-gel solution, this coating then being dried at elevated temperature and crosslinked again. The conversion element 3 is consequently formed. The surface roughness of the conversion element 3 can be reduced by way of grinding and/or polishing. It is also possible to adapt the color location of the conversion element in this way. Furthermore, the surface roughness can be reduced by way of an inactive layer, made of the clear sol-gel solution or made of a siloxane. The conversion element 3, which is on the support 9, can then be singulated and be adhesively bonded to a provided semiconductor chip 2. The conversion element 3 is adhesively bonded such that it is between the semiconductor chip 2 and the support 9. The thickness of the adhesion-promoter layer is at most 5 μm thick, preferably 3 μm or thinner.

The organic components contained are released during the production of the conversion element 3 on the support 9. This is ethanol when TEOS is used as silicate. The conversion element 3 is therefore purely inorganic and very compact. The cracks that arise during drying and crosslinking are filled during the subsequent coating with the clear sol-gel solution and reduced, with the result that a compact conversion element 3 with little cracking is produced, despite the large volume shrinkage, in the case of TEOS (approximately 80% by volume), in combination with the high rate of filling with wavelength-converting material 4, nanofillers 7 and microfillers 8. A salt can also be added to the sol-gel solution in order to reduce crack formation, this salt however being removed before further processing.

In all exemplary embodiments, the wavelength-converting material 4 of the conversion element 3 and the luminescent material of the adhesion-promoter layer 6 can comprise a phosphor mixture, for example one or more different yellow phosphors, so as to generate cold white light, or comprise a phosphor mixture, for example one or more different red phosphors and green phosphors, so as to generate warm white light.

The invention is not restricted to the exemplary embodiments by the description on the basis thereof. Rather, the invention encompasses any novel feature and any combination of features, which includes in particular any combination of features in the claims, even if this feature or this combination itself is not explicitly specified in the claims or exemplary embodiments.

### LIST OF REFERENCE SIGNS

1 Optoelectronic component

2 Semiconductor chip

3 Conversion element

4 Wavelength-converting material

5 Matrix material

6 Adhesion-promoter layer

7 Nanofillers

8 Microfillers

9 Support

10 Contact

1. An optoelectronic component having
a semiconductor chip that emits electromagnetic primary radiation of a first wavelength range during operation, and
a conversion element, wherein the conversion element comprises a wavelength-converting material and a matrix material, wherein the matrix material comprises a polysiloxane which comprises at least 90% by weight, based on the total weight of the matrix material, of condensed silicates, and the condensed silicate consists of silicon atoms and oxygen atoms,
the conversion element is configured to emit electromagnetic secondary radiation of a second wavelength range and wherein
the conversion element is downstream of the semiconductor chip and an adhesion-promoter layer is arranged between the conversion element and the semiconductor chip and/or
a support is arranged on the side of the conversion element that faces away from the semiconductor chip.

2. The optoelectronic component as claimed in the preceding claim,
in which the matrix material consists of the condensed silicate.

3. The optoelectronic component as claimed in claim 1,
wherein the adhesion-promoter layer comprises a matrix or a matrix and a luminescent material.

4. The optoelectronic component as claimed in claim 3,
wherein the matrix comprises a siloxane.

5. The optoelectronic component as claimed in claim 1,
in which the conversion element comprises nanofillers and/or microfillers.

6. The optoelectronic component as claimed in claim 5,
in which the nanofillers account for up to at most 30% by volume based on the matrix material.

7. The optoelectronic component as claimed in claim 1,
in which the second wavelength range is in the spectral range of amber light.

8. The optoelectronic component as claimed in claim 1,
in which the support is a glass substrate, a sapphire or a glass ceramic.

9. The optoelectronic component as claimed in claim 8,
in which the glass substrate is a borosilicate glass, soda-lime glass, crown glass, aluminosilicate glass, hard glass or a quartz glass.

10. A method for producing an optoelectronic component as claimed in claim 1, having the steps of:
providing a semiconductor chip configured to emit primary radiation of a first wavelength range during operation,
producing a conversion element or a precursor of a conversion element configured to emit secondary radiation of a second wavelength range,
and
applying the conversion element or the precursor of the conversion element to the semiconductor chip.

11. The method for producing an optoelectronic component as claimed in claim 10,
wherein the conversion element is formed on a support and wherein the side of the conversion element that faces away from the support is applied to the semiconductor chip or wherein the conversion element is formed on the semiconductor chip.

12. The method for producing an optoelectronic component as claimed in claim 10, wherein
the conversion element is arranged on the semiconductor chip by means of an adhesion-promoter layer.

13. The method for producing an optoelectronic component as claimed in claim 10, wherein the method temperature is at most 400° C.
